(19) United States
(12) Patent Application Publication
(10) Pub. No.: US 2025/0019828 A1
(43) Pub. Date: Jan. 16, 2025

(54) GAS INJECTION SYSTEM AND A WAFER PROCESSING APPARATUS USING THE SAME

(71) Applicant: ASM IP Holding B.V., Almere (NL)

(72) Inventors: Vivek Upadhaya, Hwaseong (KR); Yonjong Jeon, Yongin-si (KR); SungHoon Jun, Hwaseong-si (KR); DaeYoun Kim, Seo-gu (KR)

(21) Appl. No.: 18/764,500

(22) Filed: Jul. 5, 2024

Related U.S. Application Data
(60) Provisional application No. 63/525,796, filed on Jul. 10, 2023.

(51) Int. Cl. C23C 16/455; H01L 21/67

(52) U.S. Cl. CPC C23C 16/45561; H01L 21/67017

(57) ABSTRACT

A gas input structure for providing gas used in a wafer processing chamber is presented. The structure comprising a flow control ring having a sealing part and a retaining ring; and an outer body configured to encircle the flow control ring, the outer body having at least one gas tunnel, the at least one gas tunnel comprising a gas inlet, a gas outlet, and a gas flow path connecting the gas inlet and the gas outlet; wherein the retaining ring has a plurality of holes; and wherein a sealed gas space is formed between the flow control ring and the outer body, the sealed gas space containing a gas from the at least one gas tunnel to be injected through the plurality of holes into a gas channel, wherein the gas channel is connected to a wafer processing chamber.

### CROSS-REFERENCE TO RELATED APPLICATIONS

This application claims priority to U.S. Provisional Patent Application Ser. No. 63/525,796 filed Jul. 10, 2023 titled GAS INJECTION SYSTEM AND A WAFER PROCESSING APPARATUS USING THE SAME, the disclosure of which is hereby incorporated by reference in its entirety.

### FIELD OF INVENTION

The present disclosure relates to a gas injection system and a wafer processing apparatus using the gas injection system, more specifically, a gas injection system that may mix a gas or gases injected into reaction chamber(s) in a wafer processing apparatus. The present disclosure may be used both in a wafer processing apparatus equipped with or without a Remote Plasma Unit (RPU).

### BACKGROUND OF THE DISCLOSURE

Some wafer processing apparatuses that may be equipped with a showerhead might be fed with more than one gas (for example, reactant gas and precursor) into reaction chambers for wafer processing while other wafer processing apparatuses that may be equipped with an RPU and not a showerhead might be fed with one gas (for example, source gas) into reaction chambers for wafer processing.

In wafer processing, the extent a reactant gas is mixed may be important for wafer uniformity.

Therefore, the present disclosure presents a gas injection system and a wafer processing apparatus using the gas injection system for maximizing gas mixing for wafer processing.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a gas input structure for providing gas used in a wafer processing chamber, the structure comprising: a flow control ring having a sealing part and a retaining ring; and an outer body configured to encircle the flow control ring, the outer body having at least one gas tunnel, each of the gas tunnel comprising a gas inlet, a gas outlet, and a gas flow path connecting the gas inlet and the gas outlet; wherein the retaining ring has a plurality of holes; and wherein a gas space is formed and sealed between the flow control ring and the outer body to contain gas from the at least one gas tunnel to be injected through the plurality of holes.

In at least one aspect, an injection angle of the holes is between 0 degree and 80 degrees.

In at least one aspect, a downward angle of the holes is between 0 degree and 50 degrees.

In at least one aspect, a length of the flow control ring is between 4 mm and 100 mm.

In at least one aspect, a thickness of the flow control ring is between 1 mm and 10 mm.

In accordance with another embodiment there may be provided, a wafer processing apparatus, comprising: a reaction chamber and a gas input structure comprising a flow control ring having a sealing part and a retaining ring; and an outer body configured to encircle the flow control ring, the outer body having at least one gas tunnel, each of the gas tunnel comprising a gas inlet, a gas outlet, and a gas flow path connecting the gas inlet and the gas outlet; wherein the retaining ring has a plurality of holes; and wherein a gas space is formed and sealed between the flow control ring and the outer body to contain gas from the at least one gas tunnel to be injected through the plurality of holes.

In at least one aspect, an injection angle of the holes is between 0 degree and 80 degrees.

In at least one aspect, a downward angle of the holes is between 0 degree and 50 degrees.

In at least one aspect, a length of the flow control ring is between 4 mm and 100 mm.

In at least one aspect, a thickness of the flow control ring is between 1 mm and 10 mm.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 (a) illustrates one embodiment of a gas injection system according to the present disclosure in a wafer processing apparatus equipped with a remote plasma unit (RPU) and (b) illustrates another embodiment in a wafer processing apparatus equipped with a showerhead and without an RPU.

FIG. 2 illustrates a perspective view of the gas injection system according to an embodiment of the present disclosure.

FIG. 3 (a) illustrates a top-down view of FIG. 2 and (b) illustrates a flow control ring inside of the FIG. 3 (a).

FIG. 4 illustrates a sideview of FIG. 2.

FIG. 5 (a) illustrates a perspective view of the gas injection system according to another embodiment of the present disclosure and (b) illustrates a top-down view of the gas injection system of (a).

FIG. 6 (a) illustrates a top-down view of another gas injection system with 3-injection points according to another embodiment of the present disclosure and (b) illustrates a top-down view of another gas injection system with 4-injection points according to another embodiment of the present disclosure.

FIG. 7 (a) illustrates a top-down view of a flow control ring with zero degree) (0°) injection angle according to an embodiment of the present disclosure and (b) illustrates a top-down view of a flow control ring with non-zero degree injection angle according to another embodiment of the present disclosure.

FIG. 8 illustrates a side view of a flow control ring with non-zero degree downward angle according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

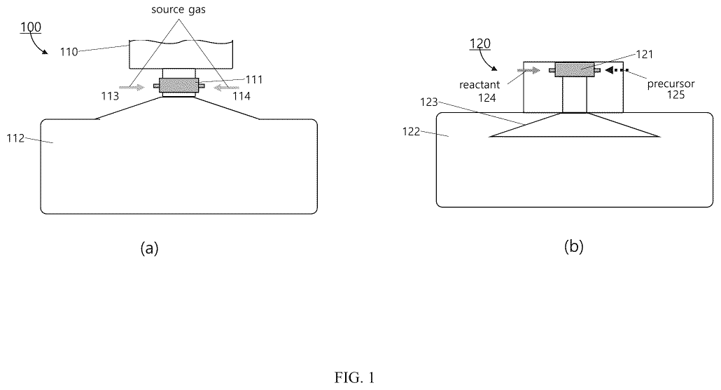

FIGS. 1 (a) and (b) illustrate two examples of how a gas injection system could be used in various wafer processing devices.

FIG. 1 (a) illustrates a wafer processing device 100 with a remote process unit (RPU) 110. In this device, source gas may be injected into a reaction chamber 112 by way of a gas injection system 111 through locations 113, 114.

FIG. 1 (b) illustrates a wafer processing device 120 with a showerhead 123 and without any RPU. In this case, reactant gas and precursor gas may be injected into the reaction chamber 122 through a gas injection system 121 in locations 124, 125 respectively.

The same gas injection system could be used in the two different devices illustrated in FIGS. 1 (a) and (b).

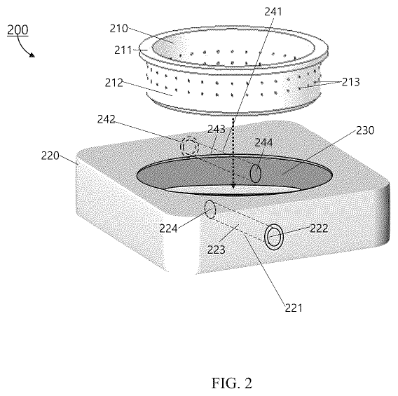

A gas injection system 200 according to an embodiment of the present disclosure is illustrated FIG. 2.

The gas injection system 200 may comprise a flow control ring 210 and an outer body 220. The flow control ring 210 may be inserted into the outer body 220 as shown in FIG. 2.

The flow control ring 210 may have a circular shape and it may have a sealing part 211 and a retaining ring 212 disposed below the sealing part 211. The sealing part 211 may be shaped to be protruded from the retaining ring 212 to seal off the space between the flow control ring 210 and the outer body 220. This space is explained below.

The outer body 220 may encircle the flow control ring 210 and may comprise more than one gas tunnels 221, 241. This outer body 220 may surround the flow control ring 210 when the flow control ring 210 is inserted into the outer body 220.

The sealing part 211 of the flow control ring 210 may be shaped to be protruded from the retaining ring 212 so that the sealing part 211 can seal a gas space 230 defined by the sealing part 211, the retaining ring 212 (flow control ring 210), and the inside of the outer body 220.

When the flow control ring 210 is inserted into the outer body 220, the gas space 230 may be sealed off from outside except the holes 213.

A gas tunnel 221 may comprise a gas inlet 222, a gas outlet 224, and a gas flow path 223 which connects the gas inlet 222 and the gas outlet 224.

There may be one or more gas tunnels 221, 241 in the outer body 220 and the other gas tunnel 241 may also comprise a gas inlet 242, a gas outlet 244, and a gas flow path 243 which connects the gas inlet 242 and the gas outlet 244.

The gas tunnels 221, 241 may be sealed off by valves (not illustrated) which would be connected to the respective gas inlets 222, 242 after gas or gases are injected into the gas tunnels 221, 241.

When the flow control ring 210 is inserted into the outer body 220, the gas space 230 may be defined by the flow control ring 210 and the outer body 220 and the gas(es) from the gas tunnels 221, 241 may be contained within the sealed gas space 230.

For example, when there are two gas tunnels 221, 241 as shown in FIG. 2, then either the same gas may be inserted into the gas tunnels 221, 241 (‘source gas’ as shown in FIG. 1 (a)) or different gases may be inserted into each of the gas tunnels 221, 241 (‘reactant and precursor’ as shown in FIG. 1 (b)).

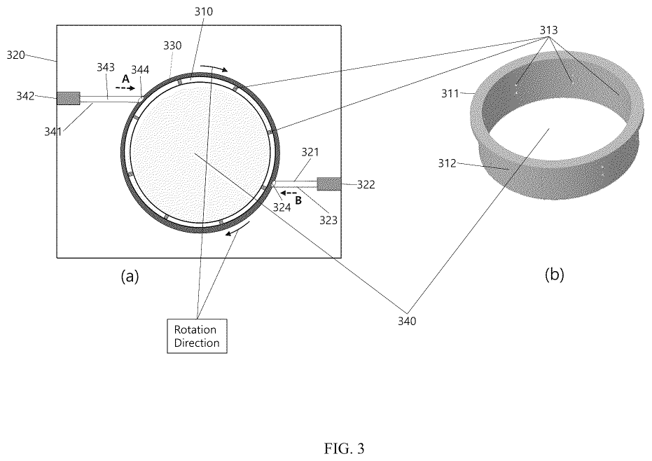

FIG. 3 (a) shows a top-down view of FIG. 2.

The shape of an outer body 320 may be a circle or a rectangular or any other shape which might be suitable for the wafer processing device to which it is attached.

In FIG. 3 (a), there may be two (2) gas tunnels 321, 341. The two opposite gas tunnels 321, 341 do not lie along a same line or plane. This feature may enable the gas circulating in the gas space 330 to move faster because the gas entering into the gas space 330 from both the gas tunnels 321, 341 may accelerate the already circulating gas in the gas space 330 since the directions of the already circulating gas in the gas space 330 (Rotation Direction) and the directions of the entering gas from both of the gas tunnels 321, 341 (A, B) are the same.

In FIG. 3 (a), the direction of the rotating gas in the gas space 330 “Rotation Direction” is clockwise and in another embodiment the rotation direction would be counterclockwise with different positions of the gas tunnels 321, 341.

Each of the gas tunnel 321, 341 may comprise a gas inlet 322, 342, a gas outlet 324, 344, and a gas flow path 323, 343. The gas flow path 323, 343 may connect the gas inlet 322, 342 and the gas outlet 324, 344, respectively. The gas inlets 322, 342 may be connected to outside pipes (not illustrated) connected to a gas supply source.

The gas from the gas inlet 322, 342 may flow through the gas flow path 323, 342 to the gas outlet 324, 344. The gas may exit the gas tunnel 321, 341 and flow into the gas space 330.

In the gas space 330, the gas may circulate around the gas space clockwise or counterclockwise according to the directions of the gas tunnels 321, 341 into the gas space 330. In this example, the gas may circulate in a clockwise direction.

The gas would be flowing into the gas channel 340 which may be connected to the reaction chamber (112 in FIGS. 1 (a) and 122 in FIG. 1 (b)).

The gas space 330 may be in between the outer body 320 and the flow control ring 310 and the gas in the gas space 330, while circulating around the gas space 330, may flow into the gas channel 340 through a plurality of holes 313 and then flow into the reaction chamber 112, 122 for wafer processing.

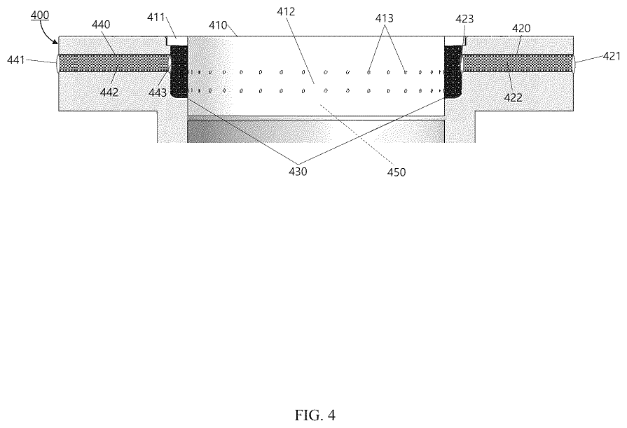

FIG. 4 illustrates a side view of the FIG. 2.

The flow control ring 410 is inserted into the outer body 400 in FIG. 4. The sealing part 411 enables a complete sealing of the gas space 430 between the outer body 400 and the flow control ring 410. There are two gas tunnels 420, 440 which may lead the gas into the gas channel 450 and finally reaction chamber (not illustrated).

The flow control ring 410 may comprise the sealing part 411, the retaining ring 412, and a plurality of holes 413 on the retaining ring 412. The gas tunnels 420, 440 may comprise gas inlets 421, 441, gas outlets 423, 443, and gas flow paths 422, 442.

Same gas or different gases may be injected into the gas inlets 421, 441. For example, the same source gas may be injected into the gas inlets 421, 441 and in other cases a reactant gas and a precursor gas would be injected into the gas inlets 421, 441 respectively.

The gas inside of the gas space 430 may circulate around the flow control ring 410 and when possible, may pass through the holes 413 into the gas channel 450 and eventually into a reaction chamber (not illustrated) for wafer processing.

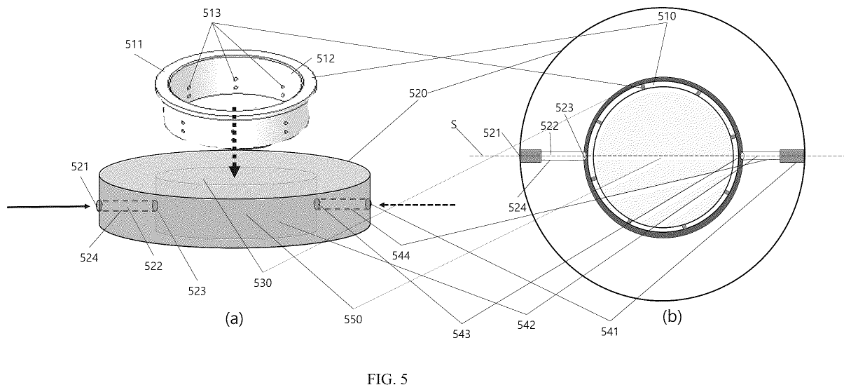

FIG. 5 (a) illustrates a perspective view of the gas injection system according to another embodiment of the present disclosure and (b) illustrates a top-down view of the gas injection system of (a).

The flow control ring 510, which may comprise a sealing part 511 and a retaining ring 512, a plurality of holes 513 on the retaining ring 512 may be clearly seen.

In this example, the outer body 520 is shaped to be a circle with a hollow center for the flow control ring 510 to be inserted.

The two gas tunnels 524, 544 each comprising a gas inlet 521, 541, a gas outlet 523, 543 and a gas flow path 522, 542. The gas injected into the gas inlets 521, 541 would be swirling around the flow control ring 510 in the gas space 530.

The gas in the gas space 530 would flow into the gas channel 550 through a plurality of holes 513 and then flow into the reaction chamber (112, 122 in FIG. 1 (a) & (b) respectively) for wafer processing.

Unlike in FIG. 3 (a), the two gas tunnels are on a same plane or line, shown by a line S.

In this embodiment, the direction of the gas circulating in the gas space 530 may be decided by chance. The gas entering the gas space 530 from the gas outlets 523, 543 may hit the flow control ring 510 and would create vortex in the gas space 530.

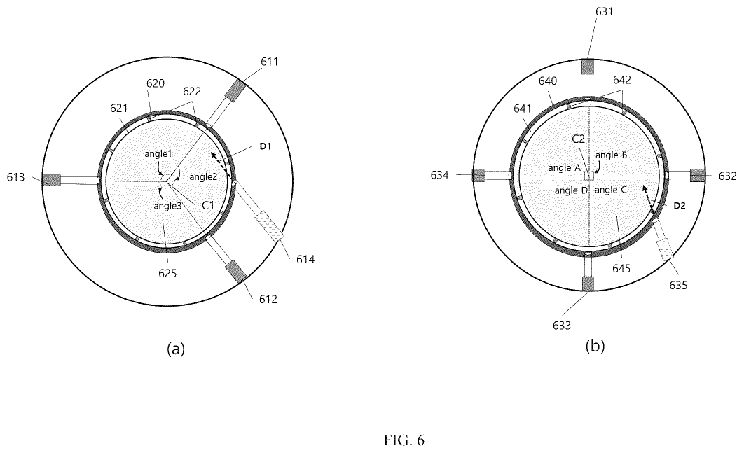

FIG. 6 (a) illustrates another embodiment of gas injection system with 3 gas tunnels and (b) illustrates another embodiment of gas injection system with 4 gas tunnels.

The angles (angle1, angle2, angle3) the gas tunnels 611, 612, 613 make among themselves illustrated in FIG. 6 (a) would be 120 degrees for maximizing the mixture of gas in the gas space 620 but this could be changed to meet the needs.

Also, in case of 4 gas tunnels, the angles (angle A, angle B, angle C, angle D) the gas tunnels 631, 632, 633, 634 make among themselves illustrated in FIG. 6 (b) would be 90 degrees for maximizing the mixture of gas in the gas space 640 but this could also be changed to meet the operating circumstances.

The directions of the gas tunnels 611, 612, 613 in FIG. 6 (a) and the gas tunnels 631, 632, 633, 634 in FIG. 6 (b) are the center points C1 and C2 of the gas channels 625, 645, respectively. However, for example, the direction of the gas tunnels 614 in FIGS. 6 (a) and 635 in FIG. 6 (b) may not be the center points C1, C2 (D1, D2, respectively)

The direction of the gas tunnels may be decided to arbitrarily to satisfy the operational processing efficiency.

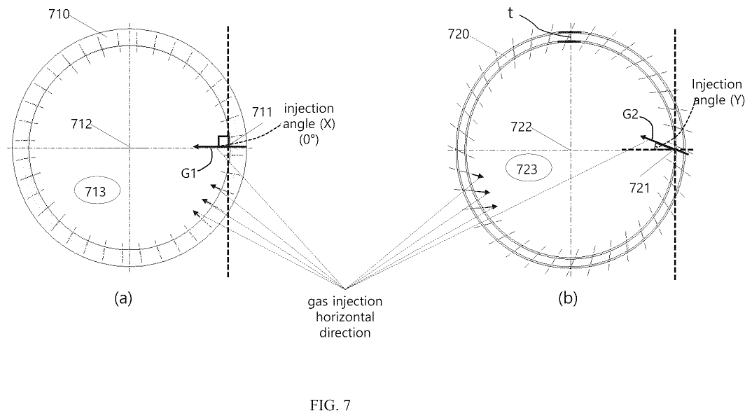

In FIG. 7 (a), the direction of the holes 711 (gas injection horizontal direction) in the flow control ring 710 may be the center 712 of the flow control ring. In this case, gas injection horizontal direction (G1) from a hole 711 is the same with the direction from the hole 711 to the center 712 of the flow control ring 710.

The angle between the gas injection horizontal direction from a hole 711 and the direction from the hole 711 to the center 712 of the flow control ring 710 would be an injection angle and in this case, the injection angle (X) would be 0 degree) (0°) and all the holes in the flow control ring 710 in FIG. 7 (a) would converge at the center 712.

In some cases, this 0-degree injection angle would mean less effective gas mixing, which results in poor uniformity and resulting product quality. Therefore, to improve the gas mixture efficiency, sometimes the injection angle (Y) may be something other than 0 just like in FIG. 7 (b). The injection angle may be chosen to meet wafer processing requirements, for example from between 0° and 80° and in this case all the holes in the flow control ring 720 in FIG. 7 (b) would not converge at the center 722.

For efficient gas injection with non-zero injection angles, the flow control ring should be thick enough to accommodate the through holes. The thickness (t) of the flow control ring 720 in FIG. 7 (b) may be chosen to meet system requirements, for example between 1 mm and 10 mm.

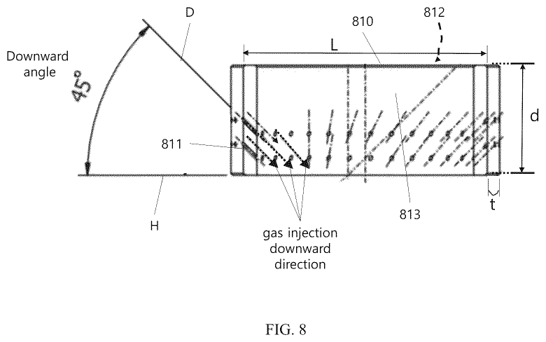

In FIG. 8, the side view of the flow control ring 810 and the holes 811 may be illustrated.

The angle between the flow control ring's horizontal side direction (H) of a hole 811 and the gas injection downward direction (D) of the hole 811 may be defined as downward angle and the downward angle of the hole 811 in FIG. 8 would be 45°. The downward angle of holes 811 would be chosen to meet processing requirements, for example between 0° and 50°.

The downward angles of the holes in a flow control ring 810 may be the same or different among themselves.

The length (d) of the flow control ring 810 may vary from 4 mm to 100 mm for maximum gas mixture effect since the length (d) of the flow control ring 810 may determine the number of the holes 811 in the flow control ring's retaining ring 813.

The internal diameter (L) of the flow control ring 810 in FIG. 8 may vary between 20 mm and 200 mm and the diameter of the holes may vary between 0.5 mm and 5 mm.

The above-described arrangement of apparatus is merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A gas input structure for providing gas used in a wafer processing chamber, the structure comprising:
a flow control ring having a sealing part and a retaining ring; and
an outer body configured to encircle the flow control ring, the outer body having at least one gas tunnel, the at least one gas tunnel comprising a gas inlet, a gas outlet, and a gas flow path connecting the gas inlet and the gas outlet;
wherein the retaining ring has a plurality of holes; and
wherein a sealed gas space is formed between the flow control ring and the outer body, the sealed gas space containing a gas from the at least one gas tunnel to be injected through the plurality of holes into a gas channel,
wherein the gas channel is connected to a wafer processing chamber.

2. The gas input structure according to the claim 1, wherein each of the plurality of holes is inclined with an injection angle and a downward angle.

3. The gas input structure according to the claim 2, wherein the injection angle of each of the plurality of holes is between 0 degree and 80 degrees.

4. The gas input structure according to the claim 2, wherein the downward angle of each of the plurality of holes is between 0 degree and 50 degrees.

5. The gas input structure according to the claim 1, wherein a length of the flow control ring is between 4 mm and 100 mm.

6. The gas input structure according to the claim 1, wherein a thickness of the flow control ring is between 1 mm and 10 mm.

7. A wafer processing apparatus, comprising:
a reaction chamber; and
a gas input structure comprising:
a flow control ring having a sealing part and a retaining ring; and
an outer body configured to encircle the flow control ring, the outer body having at least one gas tunnel, the at least one gas tunnel comprising a gas inlet, a gas outlet, and a gas flow path connecting the gas inlet and the gas outlet;
wherein the retaining ring has a plurality of holes; and
wherein a sealed gas space is formed between the flow control ring and the outer body, the sealed gas space containing a gas from the at least one gas tunnel to be injected through the plurality of holes into a gas channel,
wherein the gas channel is connected to the reaction chamber.

8. The wafer processing apparatus according to the claim 7, wherein each of the plurality of holes is inclined with an injection angle and a downward angle.

9. The wafer processing apparatus according to claim 8, wherein the injection angle of each of the plurality of holes is between 0 degree and 80 degrees.

10. The wafer processing apparatus according to claim 8, wherein the downward angle of each of the plurality of holes is between 0 degree and 50 degrees.

11. The wafer processing apparatus according to claim 7, wherein a length of the flow control ring is between 4 mm and 100 mm.

12. The wafer processing apparatus according to claim 7, wherein a thickness of the flow control ring is between 1 mm and 10 mm.
